(19) United States
(12) Patent Application Publication
(10) Pub. No.: US 2026/0024475 A1
(43) Pub. Date: Jan. 22, 2026

(54) DISPLAY MODULE AND DISPLAY APPARATUS

(71) Applicant: Wuhan Tianma Microelectronics Co., Ltd., Wuhan (CN)

(72) Inventors: Xigang LIU, Wuhan (CN); Chuan LIU, Wuhan (CN); Zhihua YU, Wuhan (CN)

(73) Assignee: Wuhan Tianma Microelectronics Co., Ltd., Wuhan (CN)

(21) Appl. No.: 18/970,982

(22) Filed: Dec. 6, 2024

(30) Foreign Application Priority Data
Jul. 18, 2024 (CN) 202410970538.9

(51) Int. Cl. G09G 3/00; G01R 31/28

(52) U.S. Cl. CPC G09G 3/006; G01R 31/2825

(57) ABSTRACT

The present application discloses a display module and a display apparatus. The display module includes a display panel, a driver chip, a test pad unit, and a first gating circuit. The display panel includes a display area and a non-display area surrounding at least part of the display area. The driver chip includes a plurality of chip pins, the plurality of chip pins includes test pins. The driver chip is bonded to the display panel to form at least two test binding units, each of the test binding units includes at least two sets of correspondingly bonded test pins and first binding pads, and the first binding pads are disposed in the non-display area of the display panel. The test pad unit is electrically connected to each of the test binding units respectively through the first gating circuit.

### CROSS-REFERENCE TO RELATED APPLICATION

This application claims priority to Chinese Patent Application No. 202410970538.9, filed on Jul. 18, 2024, which is hereby incorporated by reference in its entirety.

### TECHNICAL FIELD

The present application relates to the technical field of display, and in particular to a display module and display apparatus.

### BACKGROUND

In current display technology, the driver chip that drives the display panel is required to be bonded to the display panel. Before the display panel is shipped from the factory, the reliability of the binding connection between the driver chip and the display panel will be tested to avoid products with poor binding connections from being shipped from the factory. In the existing art, the number of pads for the binding test is large, which takes up a large amount of trace space of the display panel and affects the wiring effect.

### SUMMARY

Embodiments of the present application provide a display module and display apparatus to reduce the space occupied by a test pad unit, and facilitate the placement of other signal traces.

In a first aspect, embodiments of the present application provide a display module includes a display panel, a driver chip, a test pad unit, and a first gating circuit. The display panel includes a display area and a non-display area surrounding at least part of the display area. The driver chip includes a plurality of chip pins, and the plurality of chip pins includes test pins. The driver chip is bonded to the display panel to form at least two test binding units, each of the test binding units includes at least two sets of correspondingly bonded the test pins and first binding pads, and the first binding pads are disposed in the non-display area of the display panel. The test pad unit is electrically connected to each of the test binding units through the first gating circuit, and the test pad unit is connected to the first binding pads and the test pins in each of the test binding units through the first gating circuit to form a binding impedance testing circuit.

In a second aspect, embodiments of the present application provide a display apparatus including a display module as described in the first aspect of the present application.

The display module provided in an embodiment of the present application is provided with a test pad unit and a first gating circuit, the test pad unit is electrically connected to each test binding unit through the first gating circuit, and the test pad unit is connected to a first binding pads and a test pins in each test binding unit through the first gating circuit to form a binding impedance test circuit. Under the gating effect of the first gating circuit, the test pad unit can form a binding impedance testing circuit with different test binding units, thereby reducing the number of test pad units, reducing the space occupied by the test pad unit, and leaving a larger layout space for other signal traces, thereby reducing the difficulty of laying traces, and improving the effect of laying traces.

### BRIEF DESCRIPTION OF THE DRAWINGS

FIG. 1 is a schematic view of a display module in a related art.

FIG. 2 is a schematic view of a display module according to an embodiment of the present application.

FIG. 3 is an enlarged view of Part A shown in FIG. 2.

FIG. 4 is a cross-sectional view of a display module along a line B-B′ shown in FIG. 3.

FIG. 5 is a schematic view of another display module according to an embodiment of the present application.

FIG. 6 is a schematic view of yet another display module according to an embodiment of the present application.

FIG. 7 is a schematic view of still yet another display module according to an embodiment of the present application.

FIG. 8 is a cross-sectional view of a display module along a line C-C′ shown in FIG. 7.

FIG. 9 is a schematic view of yet another display module according to an embodiment of the present application.

FIG. 10 is a cross-sectional view of a display module along a line D-D′ shown in FIG. 9.

FIG. 11 is a schematic view of still yet another display module according to an embodiment of the present application.

FIG. 12 is a schematic view of yet another display module according to an embodiment of the present application.

FIG. 13 is a schematic view of still yet another display module according to an embodiment of the present application.

FIG. 14 is a schematic view of a display apparatus according to an embodiment of the present application.

### DETAILED DESCRIPTION

The present application is described in further detail below in connection with the accompanying drawings and embodiments. It is to be understood that the specific embodiments described herein are for the purpose of explaining the present application only and are not a limitation of the application. It is also to be noted that, for ease of description, only portions and not the entire structure related to the present application are shown in the accompanying drawings.

Terms used in embodiments of the present application are used for the sole purpose of describing particular embodiments and are not intended to limit the present application. It should be noted that the terms “having”, “comprising”, “including”, etc. described in the present application are open-ended in meaning, i.e., when describing the module” has”, ‘contains’ or ‘includes’ a first element, a second element and/or a third element, it means that the module includes other elements in addition to the first element, the second element and/or the third element. The orientation words such as “up”, “down”, “left”, “right” and the like described in the embodiments of the present application are described in the perspective shown in the accompanying drawings. They are described from the perspective shown in the accompanying drawings and should not be construed as limiting the embodiments of the present application.

It is also to be understood, in context, that when reference is made to an element being formed “above” or “below” another element, it is not only possible for it to be formed directly “above” or “below” the other element, but it is also possible for it to be formed directly “above” or “below” the other element, and it is also possible for it to be formed directly “above” or “below” the other element. “on” or ‘under’ the other element, but also indirectly ‘on’ or ‘under’ the other element by means of an intermediate element. The terms “first”, “second”, etc. are used for descriptive purposes only and do not indicate any order, number or importance, but are only used to distinguish the different components. Furthermore, the ordinal terms “first”, “second” and “third” in the present application are not intended to define a specific order, but only to distinguish between the various components. In the present application, when describing the layer A and the layer B as being “provided in the same layer”, it means that the layer A and the layer B are made of the same material and by the same process. For a person of ordinary skill in the art, the specific meaning of the above terms in the present application may be understood in specific cases.

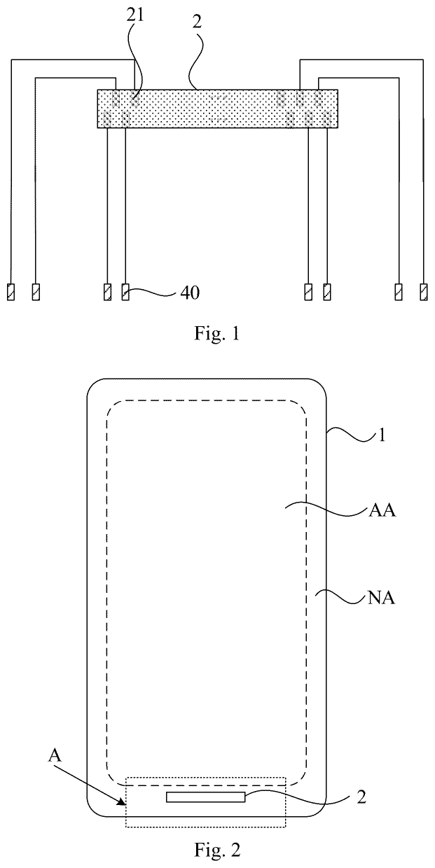

FIG. 1 is a schematic view of a display module in a related art. With reference to FIG. 1, in the related art, when performing a binding impedance testing, the test pins 21 and the test pads 40 on the driver chip 2 are in one-to-one correspondence. For example, to measure the binding state between the four test pins 21 on the left side of the driver chip 2 and the four test pins 21 on the right side of the driver chip 2, eight test pads 40 are provided on the display panel, and the test pads 40 and the test pins 21 are connected in a one-to-one correspondence to transmit test signals to the test pins 21, thereby determining the binding impedance of the test pins 21 based on the test signals, and determining whether the test pins 21 are normally bonded based on the binding impedance. The test pads 40 are formed on the display panel, and it is found that with laying the test pads 40 in the manner described above, the test pads 40 will occupy a larger space in the border of the display panel, thereby squeezing the laying space of other traces, increasing in the difficulty of wiring, and affecting the effect of wiring.

Based on the above deficiencies of the related technology, the present application provides a display module. The display module includes a display panel including a display area and a non-display area surrounding at least a portion of the display area, and a driver chip including a plurality of chip pins. The chip pins include test pins. The driver chip is bonded to the display panel to form at least two test binding units, the test binding unit includes at least two sets of correspondingly bonded test pins and first binding pads, and the first binding pads are provided in the non-display area of the display panel.

The display panel further includes a test pad unit and a first gating circuit, the test pad unit is electrically connected to each test binding unit through the first gating circuit, and the test pad unit is connected to the first binding pads and the test pins in each test binding unit through the first gating circuit to form a binding impedance testing circuit.

In the above technical solution, a test pad unit can form a binding impedance testing circuit with different test binding units under the gating effect of the first gating circuit, thereby reducing the number of test pad units, reducing the space occupied by the test pad unit, leaving a larger layout space for other signal traces, and thus reducing the difficulty of laying traces, and improving the effect of the wiring.

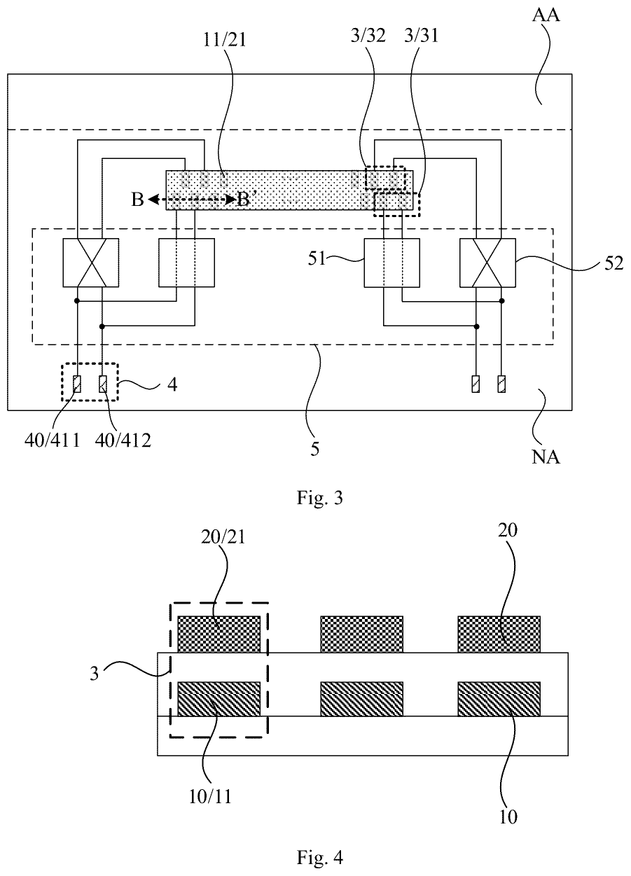

FIG. 2 is a schematic view of a display module according to an embodiment of the present application, FIG. 3 is an enlarged view of Part A shown in FIG. 2, and FIG. 4 is a cross-sectional view of a display module along a line B-B′ shown in FIG. 3 according to an embodiment of the present application. Referring to FIGS. 2 to 4, in an embodiment of the present application, the display module includes a display panel 1 including a display area AA and a non-display area NA surrounding at least a portion of the display area AA, and a driver chip 2 including a plurality of chip pins 20. The chip pins 20 include test pins 21. The driver chip 2 is bonded to the display panel 1 to form at least two test binding units 3, and each of the test binding units 3 include at least two sets of correspondingly bonded test pins 21 and first binding pads 11 provided in the non-display area NA of the display panel 1. The display panel 1 further includes a test pad unit 4 and a first gating circuit 5, and the test pad unit 4 is electrically connected to each test binding unit 3 through the first gating circuit 5 and thus electrically connected to the first binding pads 11 and the test pins 21 in each test binding unit 3 through the first gating circuit 5 to form a binding impedance testing circuit.

As shown in FIGS. 2 to 4, the display module includes the display panel 1 and the driver chip 2 bonded to the non-display area NA of the display panel 1. The drawings exemplarily show that the driver chip 2 is bonded in the lower side of the non-display area NA of the display panel 1, but is not limited to this in practice. The driver chip 2 is configured to provide various signals required for display to the display panel 1.

The non-display area NA of the display panel 1 may be provided with a plurality of chip binding pads 10, and the chip pins 20 in the driver chip 2 are connected to the chip binding pads 10 by means of an anisotropic conductive adhesive, realizing the binding of the driver chip 2 and the display panel 1. FIG. 3 illustratively shows that the chip pins 20 are within the edge of the driver chip 2, but is not limited to this in practice. In embodiments of the present application that are not shown, the chip pins 20 may extend out of the driver chip 2. The sectional view shown in FIG. 4 shows only the chip pins 20 and the chip binding pads 10, and other structures such as the driver chip 2 are not shown.

With continued reference to FIGS. 2 to 4, the chip pin 20 includes at least two test pins 21, the chip binding pad 10 includes at least two first binding pads 11, and the test pins 21 are correspondingly bonded to the first binding pads 11 to form the test binding unit 3. The test pins 21 and the first binding pads 11 of the test binding unit 3 are configured to perform binding impedance testing.

Furthermore, as shown in FIGS. 2 to 4, the non-display area NA of the display panel 1 further includes a test pad unit 4, and the test pad unit 4 may include a test pad 40, and the test pad unit 4 is configured to receive an impedance testing signal during the binding impedance testing, and the test pad unit 4 may be disposed on the side of the driver chip 2 facing away from the display area AA. It is worth noting that, in the embodiment of the present application, the display panel 1 is further provided with the first gating circuit 5, and the first gating circuit 5, the test pad unit 4, and the driver chip 2 may be disposed in a non-display area NA on the same side of the display panel 1. The test pad unit 4 is connected to the at least two test binding units 3 via the first gating circuit 5. The first gating circuit 5 has a gating function, and a single test pad unit 4 can be connected to different test binding units 3 by using the first gating circuit 5 to connect the test pad unit 4 and the test binding units 3, thereby enabling a test pad unit 4 to form a binding impedance testing circuit with different test binding units 3. The binding impedance testing circuit includes test pads 40 in the test pad unit 4, a first gating circuit 5, and chip pins 20 and first binding pads 11 in the test binding unit 3 that are gated by the first gating circuit 5.

In this arrangement, under the gating effect of the first gating circuit 5, one test pad unit 4 can form a binding impedance testing circuit with different test binding units 3, thus reducing the number of test pad units 4, that is, reducing the number of test pads 40, reducing the space occupied by the test pad units 4, and leaving a larger layout space for the other signal traces to reduce the difficulty of wiring and to enhance the effect of 1 wiring.

For the specific design of the first gating circuit 5, the embodiments of the present application are not limited, and any one of the circuits capable of realizing the gating function is within the scope of the technical solutions protected by the embodiments of the present application.

The display module provided in the embodiments of the present application is provided with a test pad unit 4 and a first gating circuit 5, the test pad unit 4 is electrically connected to each test binding unit 3 through the first gating circuit 5, and thus connected to the first binding pads 11 and the test pins 21 in each test binding unit 3 through the first gating circuit 5 to form the binding impedance testing circuit. With such an arrangement, by means of gating the first gating circuit 5, one test pad unit 4 can form a binding impedance testing circuit with different test binding units 3, thereby reducing the number of test pad units 4 and thus the space occupied by the test pad unit 4, and leaving a larger layout space for other signal traces so as to reduce the difficulty of wiring and improve the effect of wiring.

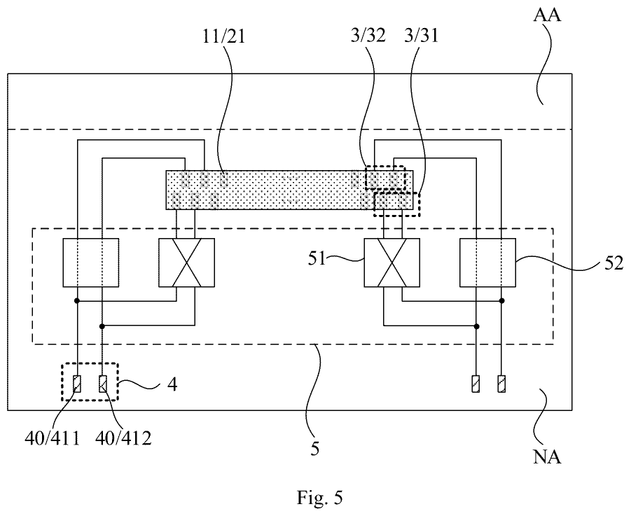

Optionally, FIG. 5 is a schematic view of another display module according to an embodiment of the present application. With reference to FIGS. 2 to 5, in a possible embodiment, the at least two test binding units 3 include at least one first test binding unit 31 and at least one second test binding unit 32, the first gating circuit 5 includes a first gating unit 51 and a second gating unit 52, and the test pad unit 4 is electrically connected to the first test binding unit 31 via the first gating unit 51 and electrically connected to the second test binding unit 32 through the second gating unit 52. The display module has a first testing phase and a second testing phase. In the first testing phase, the first gating unit 51 is turned on to enable the test pad unit 4 and the first test binding unit 31, and the test pad unit 4 is connected to the first binding pads 11 and the test pins 21 in the first binding unit 31 to form a first binding impedance testing circuit. In the second testing phase, the second gating unit 52 is turned on to enable the test pad unit 4 and the second test binding unit 32, and the test pad unit 4 is connected to the first binding pads 11 and the test pins 21 in the second test binding unit 32 to form a second binding impedance testing circuit.

As shown in FIGS. 2 to 5, in the present embodiment, the test binding unit 3 may be divided into a first test binding unit 31 and a second test binding unit 32, and the first test binding unit 31 and the second test binding unit 32 refers to two different test binding units 3 connected to the same test pad 40 in the test pad unit 4.

Specifically, the test pad unit 4 may be connected to one end of the first gating unit 51 via a trace, and the other end of the first gating unit 51 is connected to the first test binding unit 31 via a trace. The test pad unit 4 is connected to one end of the second gating unit 52 via a trace, and the other end of the second gating unit 52 is connected to the second test binding unit 32 via a trace. The above traces may be connecting traces within the display panel 1.

In this arrangement, the binding test process of the display panel 1 and the driver chip 2 may include a first testing phase and a second testing phase. In the first testing phase, as shown in FIG. 2, with the first gating unit 51 gating, the test pad unit 4 is connected to the first test binding unit 31, and the test pad unit 4, the first gating unit 51, and the test pins 21 and the first binding pads 11 in the first test binding unit 31 are connected to form a first binding impedance testing circuit for detecting the binding impedance of the first binding pads 11 and the test pins 21 in the first test binding unit 31. In the second testing phase, as shown in FIG. 5, with the first gating unit 51 gating, the test pad unit 4 is connected to the second test binding unit 32, and the test pad unit 4, the second gating unit 52, and the test pins 21 and the first binding pads 11 in the second test binding unit 32 are connected to form a second binding impedance testing circuit for detecting the binding impedance of the first binding pads 11 and the test pins 21 in the first test binding unit 32. Dashed lines within the gating unit in FIGS. 2 and 5 indicate that the gating unit is turned on, and crossed lines indicate that the gating unit is turned off.

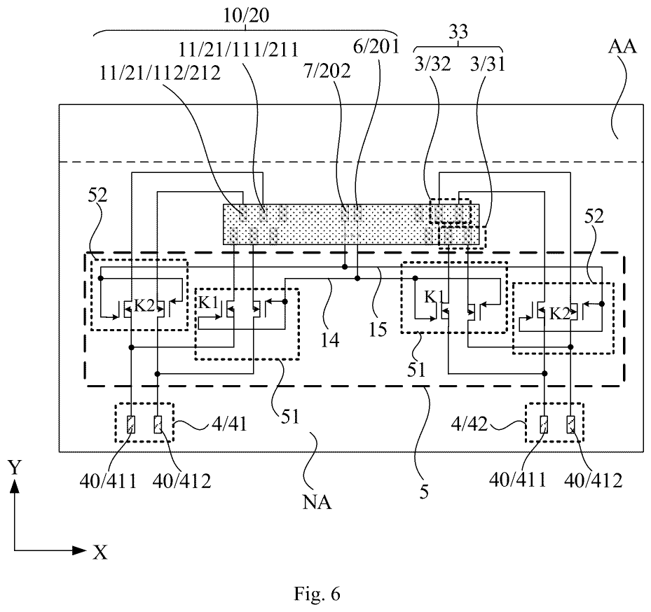

Optionally, FIG. 6 is a schematic view of yet another display module according to an embodiment of the present application. Referring to in FIG. 6, in a possible embodiment, the test pad unit 4 includes test pads 40, the first gating unit 51 includes a first switch K1, and one test pad 40 is correspondingly electrically connected to the first binding pads 11 in the first test binding unit 31 via the first switch K1. The second gating unit 52 includes a second switch K2, and another test pad 40 is correspondingly electrically connected to the first binding pads 11 in the second test binding unit 32 via the second switch K2. A control terminal of the first switch K1 is connected to the first test control terminal 6, and a control terminal of the second switch K2 is connected to the second test control terminal 7. In the first testing phase, the first switch K1 is turned on according to an active level signal transmitted by the first test control terminal 6, and the second switch K2 is turned off according to an inactive level signal transmitted by the second test control terminal 7. In the second testing phase, the first switch K1 is turned off according to an inactive level signal transmitted by the first test control terminal 6, and the second switch K2 is turned on according to an active level signal transmitted by the second test control terminal 7.

As shown in FIG. 6, the number of test pads 40 in the test pad unit 4 may be the same as the number of first binding pads 11 in the test binding unit 3 to which the test pad unit 4 is connected. For example, FIG. 6 shows that the test binding unit 3 includes two first binding pads 11, so the test pad unit 4 may include two test pads 40, which is not limited thereto in practice.

The gating unit may include a switching element, which includes, but not limited to, a transistor. The first gating unit 51 includes a first switch K1, and the number of first switches K1 may be the same as the number of test pads 40 in the test pad unit 4. The test pads 40 are correspondingly connected to a first end of the first switch K1 via a trace, and a second end of the first switch K1 is connected to the corresponding first binding pads 11 in the first test binding unit 31 via a trace. Correspondingly, the second gating unit 52 includes a second switch K2, and the number of second switch K2 may be the same as the number of test pads 40 in the test pad unit 4. The test pads 40 are correspondingly connected to the first end of the second switch K2 via a trace, and the second end of the second switch K2 is connected to the corresponding first binding pads 11 in the second test binding unit 32 via a trace.

Furthermore, the first switch K1 and the second switch K2 each include a control terminal, and the control terminal of the first switch K1 is electrically connected to the first test control terminal 6 to receive a test control signal from the first test control terminal 6 and to be turned on or off in response to the test control signal. With the first switch K1 on, the test pad unit 4 is connected to the first test binding unit 31, and with the first switch K1 off, the test pad unit 4 is disconnected from the first test binding unit 31. The control terminal of the second switch K2 is electrically connected to the second test control terminal 7 to receive a test control signal from the second test control terminal 7 and to be turned on or off in response to the test control signal. With the second switch K2 on, the test pad unit 4 is connected to the second test binding unit 32, and with the second switch K2 off, the test pad unit 4 is disconnected from the second test binding unit 32.

Specifically, in the first testing phase, the test control signal sent by the first test control terminal 6 to the first switch K1 is an active level signal, and the first switch K1 turn on in response to the active level signal. At the same time, the test control signal sent by the second test control terminal 7 to the second switch K2 is an inactive level signal, and the second switch K2 maintains an off state in response to the inactive level signal, so that the test signal in the test pad unit 4 is transmitted to the first test binding unit 31. In the second testing phase, the test control signal sent by the second test control terminal 7 to the second switch K2 is an active level signal, and the second switch K2 turn on in response to the active level signal. At the same time, the test control signal sent by the first test control terminal 6 to the first switch K1 is an inactive level signal, and the first switch K1 maintains an off state in response to the inactive level signal, so that the test signal in the test pad unit 4 is transmitted to the second test binding unit 32.

Optionally, with continued reference to FIG. 6, the control terminal of each first switch K1 in the same first gating unit 51 is connected to the same first test control terminal 6, and the control terminal of each second switch K2 in a same second gating unit 52 is connected to the same second test control terminal 7.

In the present embodiment, the control terminals of all the first switches K1 in the same first gating unit 51 are connected to the same first test control terminal 6, and the same first test control terminal 6 sends test control signals to the plurality of first switches K1. The control terminals of all the second switches K2 in the same second gating unit 52 are connected to the same second test control terminal 7, and the same second test control terminal 7 sends test control signals to the plurality of second switches K2. The different first switches K1 in the same first gating unit 51 have the same control timing, and in the first testing phase, all the first switches K1 in the same first gating unit 51 are turned on synchronously. The different second switches K2 in a same second gating unit 52 have the same control timing, and in the second testing phase, all the second switch K2 in a same second gating unit 52 are turned on synchronously to improve the synchronization of the switching elements in the same gating unit.

In other embodiments not shown, it is possible that the control terminals of the first switches K1 in the same first gating unit 51 are connected to different first test control terminals 6, respectively. The control terminals of the second switches K2 in a same second gating unit 52 are connected to different second test control terminals 7, respectively. Therefore, each first switch K1 or second switch K2 is controlled by the corresponding test control terminals to improve the control flexibility of the first switch K1 or the second switch K2.

It needs to be clarified is that the resistances of the switching elements and the connecting traces may be different, the first gating circuit 5 is added in the connecting path between the test pad unit 4 and the test binding unit 3, which may enable the binding impedance of the first binding pad 11 and the test pin 21 to be different from the binding impedance when the first gating circuit 5 is added. Therefore, in the embodiment of the present application, the resistance of the first switch K1 (or the second switch K2) can be compensated in the binding impedance testing phase, that is, the influence of the switching element resistance on the binding impedance can be removed to ensure the accuracy of the binding impedance testing.

Furthermore, with continued reference to FIG. 6, in a possible embodiment, the at least two test binding units 3 comprise at least two first test binding units 31 and at least two second test binding units 32. The number of first gating units 51 is the same as the number of first test binding units 31, and the number of second gating units 52 is the same as the number of second test binding units 32. The control terminals of the first switches K1 in the first gating units 51 each are connected to the same first test second terminal 6, and the control terminals of the second switches K2 in the second gating units 52 each are connected to the same second test control terminal 7.

As shown in FIG. 6, the first test binding unit 31 and the second test binding unit 32 connected to the same test pad unit 4 may be defined as a testing binding group 33, and in the embodiment of the present application, the display module may include at least two test binding sets 33. Accordingly, the first gating circuit 5 includes at least two first gating units 51 and at least two second gating units 52, and each testing binding group 33 is correspondingly connected to the first gating unit 51 and the second gating unit 52, that is, the first gating units 51 are connected to the first test binding units 31 in a one-to-one correspondence, and the second gating units 52 are connected to the second test binding units 32 in a one-to-one correspondence.

The number of test pad units 4 is the same as the number of test binding sets 33, and one test pad unit 4 is connected to the first test binding unit 31 and the second test binding unit 32 in one of test binding sets 33. Specifically, one test pad unit 4 is connected to one first test binding unit 31 via the corresponding first gating unit 51 and connected to one second test binding unit 32 via the corresponding second gating unit 52.

Referring to FIG. 6, in the present embodiment, a plurality of first switches K1 in the first gating unit 51 are connected to the same first test control terminal 6, and a plurality of second switches K2 in the second gating unit 52 are connected to the same second test control terminal 7. In this manner, the control timings of a plurality of the first switches K1 in the first gating circuit 5 are all the same, and the control timings of a plurality of the second switches K2 in the first gating circuit 5 are all the same. In the first testing phase, the test pad unit 4 may be utilized to simultaneously perform the binding impedance testing on all the first test binding units 31 in the display module, and in the second testing phase, the test pad unit 4 may be utilized to simultaneously perform the binding impedance testing on all the second test binding units 32 in the display module, which ensures that the display module has a high binding impedance testing efficiency.

Still referring to FIG. 6, in a possible embodiment, the at least two test binding units 3 include two first test binding units 31 and two second test binding units 32. The two first test binding units 31 are respectively close to the opposite side edges of the driver chip 2 in the first direction X, and the two second test binding units 32 are respectively close to the opposite side edges of the driver chip 2 in the first direction X. The first direction X is parallel to the arrangement direction of the chip pins 20 in the driver chip 2. The display panel 1 includes two test pad units 4, and one of test pad units 4 is connected to one of first test binding units 31 through the corresponding first gating unit 51 and is connected to one of second test binding units 32 through the corresponding second gating unit 52.

As shown in FIG. 6, the test pins 21 may be the part of the chip pins 20 that are located on two sides of the arrangement direction of the chip pins 20, and the chip binding pad 10 that is correspondingly bonded to the chip pins 20 serves as the first binding pad 11. In accordance with the direction shown in the drawings, the first direction X is a left-right direction, the two sets of correspondingly bonded chip pins 20 and first binding pads 11 close to one side edge (e.g., the left side edge) of the driver chip 2 in the first direction X constitute one first test binding unit 31, and the other two sets of correspondingly bonded chip pins 20 and first binding pads 11 constitute a second test binding unit 32. The two sets of correspondingly bonded chip pins 20 and first binding pads 11 close to the other side edge (e.g., the right side edge) of the driver chip 2 in the first direction X constitute a first test binding unit 31, and the other two sets of correspondingly bonded chip pins 20 and the first binding pads 11 constitute one first test binding unit 32, that is, the display panel 1 is provided with two sets of test binding sets 33, which are respectively close to the two side edges of the driver chip 2 in the first direction X. In other words, the first test binding unit 31 and the second test binding unit 32 are provided on each side of the driver chip 2 in the first direction X.

Furthermore, referring to FIG. 6, the test pad units 4 may include a first test pad unit 41 and a second test pad unit 42, the first test pad unit 41 may be close to one side edge (e.g., the left side edge) of the driver chip 2 in the first direction X, and the second test pad unit 42 may be close to the other side edge (e.g., the right side edge) of the driver chip 2 in the first direction X. The first test pad unit 41 is connected to one set of test binding sets 33 (including a first test binding unit 31 and a second test binding unit 32) via one set of a first gating unit 51 and a second gating unit 52, and the second test pad unit 42 is connected to the other set of test binding sets 33 (including a first test binding unit 31 and a second test binding unit 32) via the other set of a first gating unit 51 and a second gating unit 52.

With this arrangement, the binding impedance testing of the test binding units 3 on the two side edges of the driver chip 2 can be realized by the two test pad units 4. Considering that the driver chip 2 usually has a regular shape (mostly rectangular), in a condition where when the driver chip 2 is pressed together with the display panel 1, there is a problem of poor binding due to uneven force, and the poor binding is most likely to occur on the two side edges of the driver chip 2 in the first direction X. Therefore, in the present embodiment, two first test binding units 31 are provided close to the two opposite side edges of the driver chip 2 in the first direction X, and two second test binding units 32 are provided close to the two opposite edges of the driver chip 2 in the first direction X. Therefore, the binding state of the two side edges of the driver chip 2 in the first direction X can be tested, which not only meets the requirement of improving the reliability of the evaluation result, but also does not cause a significant increase in cost and the problem of occupying more chip pins 20.

Optionally, with continued reference to FIG. 6, in some embodiments, the chip pins 20 further include a first control pin 201 and a second control pin 202. The first control pin 201 serves as the first test control terminal 6 and is electrically connected to the control terminal of the first switch K1, and the second control pin 202 serves as the second test control terminal 7 and is electrically connected to the control terminal of the second switch K2.

As shown in FIG. 6, the first control pin 201 and the second control pin 202 may be chip pins 20 other than the test pins 21. As described above, the test pins 21 are chip pins 20 on two side edges of the driver chip 2 in the first direction X, and then the first control pins 201 and the second control pins 202 may be disposed between the test pins 21 on two sides of the driver chip 2. In the binding impedance testing phase, the first control pin 201 may be used as the first test control terminal 6 to transmit a test control signal from the first control pin 201 to the first switch K1. The second control pin 202 may be used as the second test control terminal 7 to transmit a test control signal from the second control pin 202 to the second switch K2. In the normal use stage, the first control pin 201 and the second control pin 202 can be normally used as the signal transmission pins of the driver chip 2 after the display module is shipped from the factory.

In this arrangement, there is no need to additionally set up the first test control terminal 6 and the second test control terminal 7, which eliminates the process of the first test control terminal 6 and the second test control terminal 7, and does not additionally occupy the space of the display panel 1.

The first control pin 201 and the second control pin 202 are bonded to the corresponding chip binding pads 10, and the corresponding chip binding pads 10 can be connected to control binding pads (not shown in the drawings) through traces (not shown in the drawings) in the display panel 1. In the binding impedance testing phase, testing equipment may be used to provide a test control signal to the control binding pad through program settings, so that the test control signal is transmitted to the first gating circuit 5 by using the first control pin 201 and the second control pin 202.

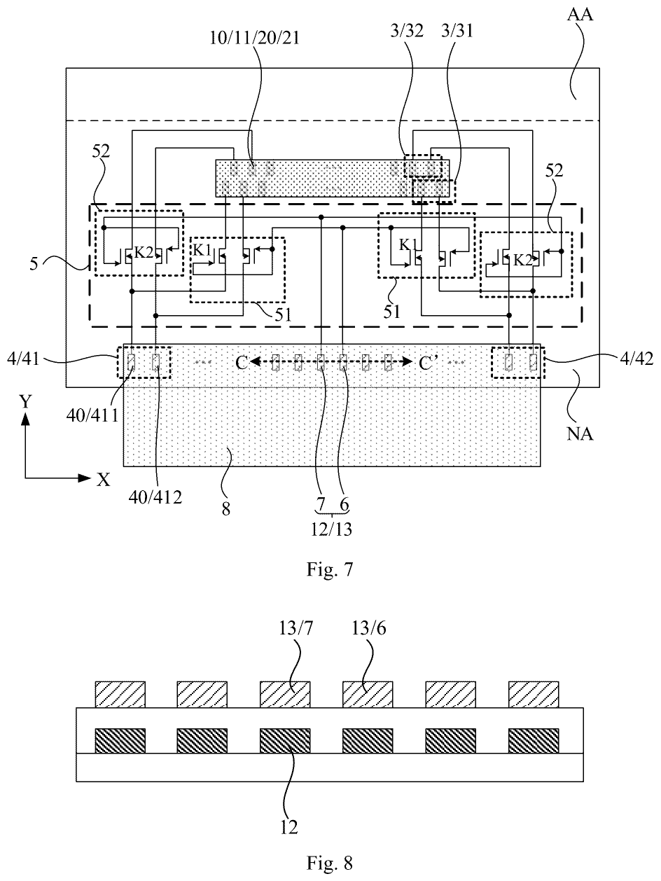

Optionally, FIG. 7 is a schematic view of still yet another display module according to an embodiment of the present application. FIG. 8 is a cross-sectional view of a display module along a line C-C′ shown in FIG. 7. Referring to FIGS. 7 and 8, in other embodiments, the display module further includes a flexible circuit board 8 bonded to the non-display area NA, and the first test control terminal 6 and the second test control terminal 7 are integrated into the flexible circuit board 8.

As shown in FIGS. 7 and 8, the flexible circuit board 8 may be bonded to the side of the driver chip 2 facing away from the display area AA. For example, a second binding pad 12 may be provided in the display panel 1, and the second binding pad 12 is disposed on the side of the chip binding pad 10 facing away from the display area AA. The flexible circuit board 8 may include third binding pads 13, and the third binding pad 13 may be connected to the second binding pad 12 through anisotropic conductive glue to achieve binding of the flexible circuit board 8 and the display panel 1.

In the present embodiment, the first test control terminal 6 and the second test control terminal 7 may be provided in the flexible circuit board 8. For example, part of the third binding pads 13 may be used also as the first test control terminal 6 and the second test control terminal 7 (as shown in the drawings), or the first test control terminal 6 and the second test control terminal 7 may be electrically connected to the corresponding third binding pads 13. The control terminal of the first switch K1 of the first gating unit 51 and the control terminal of the second switch K2 of the second gating unit 52 are electrically connected to corresponding second binding pads 12, respectively. In the binding impedance testing phase, testing equipment may be used to provide test control signals to the first test control terminal 6 and the second test control terminal 7, so that the test control signals may be transmitted to the first gating circuit 5 by using the flexible circuit board 8.

At least part of the second binding pads 12 can be electrically connected to the chip binding pads 10 through traces (not shown in the drawings) in the display panel 1, thereby realizing electrical connection between the flexible circuit board 8 and the driver chip 2, so that the driver chip 2 can receive the electrical signals from the flexible circuit board 8.

Optionally, with continued reference to FIG. 6, the display panel 1 further includes a first test control signal line 14 and a second test control signal line 15 that are disposed on the side of the driver chip 2 facing away from the display area AA. The control terminal of the first switch K1 is electrically connected to the first test control terminal 6 through the first test control signal line 14, and the control terminal of the second switch K2 is electrically connected to the second test control terminal 7 through the second test control signal line 15.

As shown in FIG. 6, the first test control signal line 14 is configured to connect the first test control terminal 6 and the control terminals of the plurality of first switches K1, and the second test control signal line 15 is configured to connect the second test control terminal 7 and the control terminals of the plurality of second switches K2. The first test control signal line 14 and the second test control signal line 15 can be the traces in the display panel 1 described above. In order to ensure the connection effect between the driver chip 2 and the signal traces in the display area AA of the display panel 1, the driver chip 2 is generally bonded to the non-display area NA that is relatively close to the display area AA, so that there is a large space on one side of the driver chip 2 facing away the display area AA. Therefore, in the present embodiment, the first test control signal lines 14 and the second test control signal lines 15 can be arranged in the non-display area NA on the side of the driver chip 2 facing away from the display area AA, leaving enough layout space for the first test control signal lines 14 and the second test control signal lines 15.

Optionally, taking for example that the chip pins 20 of the driver chip 2 are used also as the first test control terminal 6 and the second test control terminal 7, the first test control signal line 14 and the second test control signal line 15 may each include multiple branches extending in the first direction X and the second direction Y, respectively. The second direction Y intersects the first direction X. The specific layout of the first test control signal line 14 and the second test control signal line 15 is not limited. Those skilled in the art can set it according to actual needs.

Optionally, in some embodiments, the test pin 21 in the first test binding unit 31 is a signal input pin of the driver chip 2, and the test pin 21 in the second test binding unit 32 is a signal output pin of the driver chip 2.

The signal input pins of the driver chip 2 refer to chip pins 20 corresponding to part of the chip binding pads 10 connected to the flexible circuit board 8, and the signal output pins refer to chip pins 20 corresponding to the chip binding pads 10 connected to the signal traces in the display area AA. The plurality of signal input pins are arranged along the first direction X to form a signal input pin group, and the plurality of signal output pins are arranged along the first direction X to form a signal output pin group. The signal input pin group may be disposed on the side of the signal output pin group facing away from the display area AA, that is, the signal output pins are closer to the display area AA, and the signal input pins are closer to the flexible circuit board 8.

In the present embodiment, part of the signal input pins of the driver chip 2 are used as test pins 21 in the first test binding unit 31, and part of the signal output pins of the driver chip 2 are used as test pins 21 in the second test binding unit 32. In the first testing phase, a binding impedance testing is performed on the signal input pins of the driver chip 2 and the corresponding first binding pads 11. In the second testing phase, a binding impedance testing is performed on the signal output pins of the driver chip 2 and the corresponding first binding pads 11. Therefore, one test pad unit 4 is used to test both the binding state of the signal input pin and the binding state of the signal output pin, ensuring the comprehensiveness and accuracy of the binding impedance testing.

Optionally, still referring to FIG. 6, in the same test binding unit 3, the first binding pads 11 includes an input binding pad 111 and an output binding pad 112, and the test pins 21 includes a first test pin 211 and a second test pin 212; the input binding pad 111 is bonded to the first test pin 211, the output binding pad 112 is bonded to the second test pin 212, and the first test pin 211 and the second test pin 212 are shorted. The test pad unit 4 includes an input test pad 411 and an output test pad 412. The input test pad 411 is connected with the input binding pad 111 in the test binding unit 3 through the first gating circuit 5, and the output test pad 412 is connected with the output binding pad 112 in the test binding unit 3 through the first gating circuit 5. The input test pad 411, the input binding pad 111, the first test pin 211, the second test pin 212, the output binding pad 112 and the output test pad 412 are connected to form a binding impedance testing circuit.

Specifically, in the present embodiment, one test binding unit 3 may include two sets of test pins 21 and first binding pads 11 that are correspondingly bonded, one set including the first test pins 211 and input binding pads 111 that are correspondingly bonded, and the other set including the second test pins 212 and output binding pads 112 that are correspondingly bound. The first test pin 211 and the second test pin 212 are shorted, that is, the first test pin 211 and the second test pin 212 are directly electrically connected in the driver chip 2.

Correspondingly, one test pad unit 4 may include an input test pad 411 and an output test pad 412. The input test pad 411 is connected to the input binding pad 111 through the first gating circuit 5, and the output test pad 412 is connected to the output binding pad 112 through the first gating circuit 5. In the binding impedance testing phase, when the first gating circuit 5 is used to enable part of the test pad unit 4 and the test binding unit 3, the input test pad 411, the input binding pad 111, the first test pin 211, the second test pin 212, the output binding pad 112, and the output test pad 412 that are enabled by gating are sequentially connected to form the binding impedance testing circuit. The binding impedance of the test binding unit 3 can be calculated by electrical signals changes on the input test pad 411 and the output test pad 412.

It should be noted that any one of the first binding pads 11 in the same test binding unit 3 may be an input binding pad 111, and the test pin 21 that is correspondingly bonded to the first binding pads 11 may be a first test pin 211. The other one of the first binding pads 11 may be an output binding pad 112, and the test pin 21 that is correspondingly bonded to the first binding pads 11 may be a second test pin 212. Any one of the test pads 40 in the same test pad unit 4 may be an input test pad 411, and the other one of test pads 40 may be an output test pad 412. It suffices to ensure that the input test pad 411 is connected to the input binding pad 111, and the output test pad 412 is connected to the output binding pad 112. The impedance testing signal enters the bound impedance testing circuit from the input test pad 411 and outputs from the output test pad 412.

For example, still referring to FIG. 6 and taking for example that two first test binding units 31 are respectively close to opposite side edges of the driver chip 2 in the first direction X, and two second test binding units 32 are respectively close to opposite side edges of the driver chip 2 in the first direction X, the display panel 1 may include four input binding pads 111 and four output binding pads 112. Correspondingly, the display panel 1 may include two test pad units 4, two first gating units 51, and two second gating units 52; each test pad unit 4 includes the above-mentioned input test pad 411 and output test pad 412, each first gating unit 51 includes two first switches K1, and each second gating unit 52 includes two second switches K2, that is, the display panel 1 includes four first switches K1 and four second switches K2. Taking for illustration the two test binding units 3 close to the left edge of the driver chip 2 in the first direction X, in one first test binding unit 31, the input binding pad 111 is connected to the input test pad 411 through a first switch K1, and the output binding pads 112 is connected to the output test pad 412 through another first switch K1; in one second test binding unit 32, the input binding pad 111 is connected to the input test pad 411 through a second switch K2, and the output binding pads 112 is connected to the output test pad 412 through another second switch K2. The two test binding units 3 are connected to the first test pad unit 41 through the above-mentioned first switch K1 and second switch K2. The two test binding units 3 close to the other edge of the driver chip 2 in the first direction X are connected to the second test pad unit 42 in the above-mentioned connection manner, and this will not be described in detail in the present application.

Furthermore, the control terminals of the four first switches K1 can be connected to the same first test control terminal 6, and the control terminals of the four second switches K2 can be connected to the same second test control terminal 7. In the first testing phase, the program provides an active level signal to the first test control terminal 6 and an inactive level signal to the second test control terminal 7, so that the first switches K1 are turned on and the second switches K2 are turned off. The input test pad 411, the output test pad 412, and the input binding pad 111 and the output binding pad 112 in the first second test binding unit 31 are connected to form a first binding impedance testing circuit, thereby testing the binding state of the signal input pins of the driver chip 2. In the second testing phase, the program provides an active level signal to the second test control terminal 7 and an inactive level signal to the first test control terminal 6, so that the second switches K2 are turned on and the first switches K1 are turned off. The input test pad 411, the output test pad 412, and the input binding pads 111 and the output binding pad 112 in the second test binding unit 32 are connected to form a second binding impedance testing circuit, thereby testing the binding of the signal output pins of the driver chip 2.

It should be noted that in the first switch K1 (or second switch K2) connecting the input test pad 411 and the input binding pad 111, the first end of the first switch K1 (or second switch K2) is its input end, and the second end of the first switch K1 (or second switch K2) is its output end. In the first switch K1 (or second switch K2) connecting the output test pad 412 and the output binding pad 112, the first end of the first switch K1 (or second switch K2) is its output end, and the second end is its input end. In the binding impedance testing circuit, the test signal is transmitted to the input binding pad 111 through the input test pad 411, the first end and the second end of one of the first switches K1 (or second switch K2) sequentially, and then transmitted to the output test pad 412 through the first test pin 211, the second test pin 212, the output binding pad 112, the second end and the first end of the other first switch K1 (or the second switch K2) sequentially.

In the above solution, only four test pads 40 need to be provided in the display panel 1, which occupies less space. It is sufficient to use four test probes to provide signals to the test pads 40. The above binding impedance testing can be carried out simultaneously with the display module lighting test, thereby improving the efficiency of the production line.

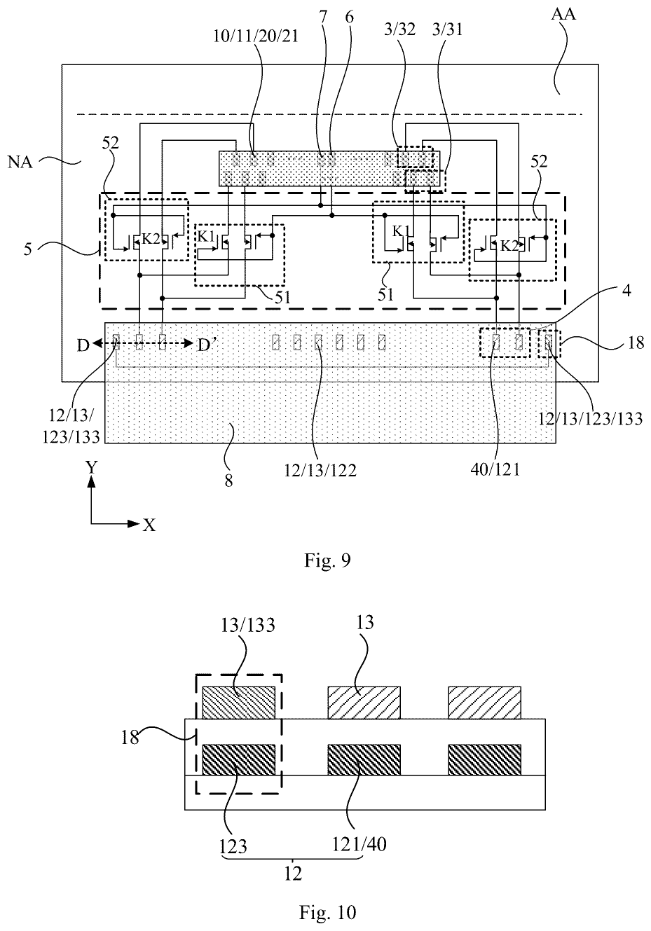

Optionally, FIG. 9 is a schematic view of yet another display module according to an embodiment of the present application. Referring to FIG. 9, the display module further includes a flexible circuit board 8, which is bonded to the non-display area NA. The display panel 1 includes a plurality of second binding pads 12, the flexible circuit board 8 includes a plurality of third binding pads 13, the second binding pads 12 are correspondingly bonded to the third binding pads 13, respectively, and part of the second binding pads 12 form the test pad unit 4.

The binding methods of the flexible circuit board 8 and the display panel 1 are all described in the above embodiments and will not be repeated here. In the present embodiment, part of the second binding pads 12 can be used as the test pads 40 to form the test pad unit 4. Specifically, the second binding pad 12 may include a first sub-binding pad 121 and a second sub-binding pad 122. The first sub-binding pad 121 is the test pad 40 in the test pad unit 4, and the second sub-binding pad 122 is directly connected to the corresponding chip binding pad 10 through traces in the display panel 1 to realize electrical connection between the flexible circuit board 8 and the driver chip 2.

The first sub-binding pads 121 may be disposed on both sides of the second sub-binding pads 122 in the first direction X, and the second sub-binding pads 122 may overlap with the driver chip 2 in the second direction Y. The first sub-binding pad 121 serves as the test pad 40 and is connected to the test binding unit 3 disposed at the edge of the driver chip 2, the layout of switching elements, traces, and the like between the test pad 40 and the test binding unit 3 is relatively simple.

Optionally, FIG. 10 is a cross-sectional view of a display module along a line D-D′ shown in FIG. 9. Referring to FIGS. 9 and 10, in a possible embodiment, the second binding pads 12 include at least one first test binding pad 123, the third binding pads 13 include at least one second test binding pad 133, and the first test binding pad 123 is correspondingly bonded to the second test binding pad 133 to form a test binding structure 18. The first test binding pads 123 in two of test binding structures 18 are electrically connected to enable the two test binding structures 18 to be connected to form a third binding impedance testing circuit.

As shown in FIGS. 9 and 10, in addition to the first sub-binding pads 121 and the second sub-binding pads 122 described above, the second binding pads 12 may further include a first test binding pad 123, the number of which is not limited. The third binding pad 13 bonded correspondingly to the first test binding pad 123 is a second test binding pad 133. The first test binding pad 123 and the second test binding pad 133 constitute a test binding structure 18. The test binding structure 18 is configured to test the binding impedance between the flexible circuit board 8 and the display panel 1, thereby detecting the binding condition between the flexible circuit board 8 and the display panel 1.

Specifically, the impedance testing phase of the display panel 1 may further include a third testing phase. In the third testing phase, the first test binding pads 123 in different test binding structures 18 may be connected, and the connected first test binding pads 123 and the corresponding second test binding pads 133 form the third binding impedance testing circuit. The binding impedance of the test binding structure 18 may be calculated by transmitting the impedance testing signal may be to one second test binding pads 133, and detecting the signal output by the other connecting second test binding pad 133, thereby detecting the binding state between the flexible circuit board 8 and the display panel 1 by using the third binding impedance testing circuit.

The third testing phase may be executed simultaneously with any of the first testing phase and the second testing phase, or the third testing phase may be executed separately, and embodiments of the present application are not limited herein.

In the present embodiment, part of the second binding pads 12 serves as the test binding structure 18 to test the binding impedance of the flexible circuit board 8. Whether the flexible circuit board 8 is normally bonded can be determined in the binding impedance testing phase to ensure normal signal transmission between the flexible circuit board 8 and the driver chip 2 during subsequent application of the display panel 1.

In the embodiment shown in FIG. 9, the two first test binding pads 123 are shorted through traces in the display panel 1 to form two test binding structures 18 that are electrically connected, but the practice is not limited to this. In this arrangement, in the third testing phase, the binding impedance of the flexible circuit board 8 and the display panel 1 can be detected by transmitting an impedance testing signal by the testing equipment to the second test binding pads 133 in the two electrically connected test binding structures 18.

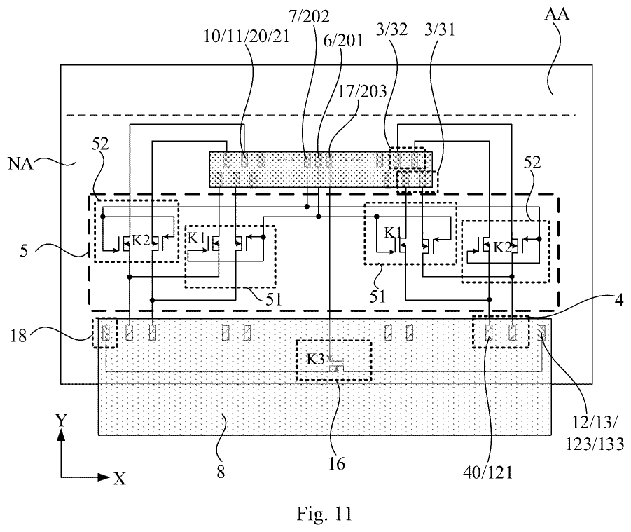

FIG. 11 is a schematic view of still yet another display module according to an embodiment of the present application. Referring to FIG. 11, in some embodiments, the display panel 1 may further include a second gating circuit 16, the first end and the second end of which are respectively connected to different first test binding pads 123, and the control terminal of which is connected to a third test control terminal 17. The second gating circuit 16 gates the two first test binding pads 123 according to a control signal from the third test control terminal 17.

The difference between the embodiment shown in FIG. 11 and the embodiment shown in FIG. 9 is that in the embodiment shown in FIG. 11, a second gating circuit 16 is provided in the display panel 1, and the first test binding pads 123 in different test binding structures 18 are gated by the second gating circuit 16.

Specifically, the second gating circuit 16 may include a third switch K3, the first end (or second end) of the third switch K3 may be the first end of the second gating circuit 16, and the second end (or first end) of the third switch K3 may be the second end of the second gating circuit 16, that is, the first end and the second end of the third switch K3 are connected between different first test binding pads 123. The control terminal of the third switch K3 may be the control terminal of the second gating circuit 16 and connected to the third test control terminal 17. In the third testing phase, testing equipment can be used to provide an active level signal to the third test control terminal 17 through a program, and the third switch K3 is turned on in response to the active level signal, so that different first test binding pads 123 are connected. In other testing phase, the inactive level signal can be provided to the third test control terminal 17 through a program, and the third switch K3 is turned off in response to the inactive level signal, so that different first test binding pads 123 are disconnected.

The number of third switches K3 in the second gating circuit 16 is not limited. The embodiment shown in FIG. 11 illustratively shows one third switch K3 and one third test control terminal 17. The connection between the two test binding structures 18 can be realized through one third test control terminal 17 and the correspondingly connected third switch K3, but is not limited to this.

Further optionally, as shown in FIG. 11, a plurality of second binding pads 12 are arranged in the first direction X, which is parallel to the arrangement direction of the chip pins 20 in the driver chip 2. The second binding pads 12 include two first test binding pads 123 respectively disposed on two sides of the test pad unit 4 in the first direction X.

The second binding pads 12 are arranged in the first direction X. In the present embodiment, the two second binding pads 12 disposed at the outermost sides in the first direction X may serve as the first test binding pads 123, and the correspondingly bonded third binding pads 13 can be used as the second test binding pads 133. That is, the display module includes two test binding structures 18 that are close to both side edges of the flexible circuit board 8 in the first direction X.

In this arrangement, in the third testing phase, the second gating circuit 16 is used to connect the test binding structures 18 disposed at both sides of the flexible circuit board 8 in the first direction X, so that it is possible to test the binding state of the both side edges in the first direction X of the flexible circuit board 8, which can not only meet the detection requirements for binding reliability, but also not occupy too many second binding pads 12 (third binding pads 13).

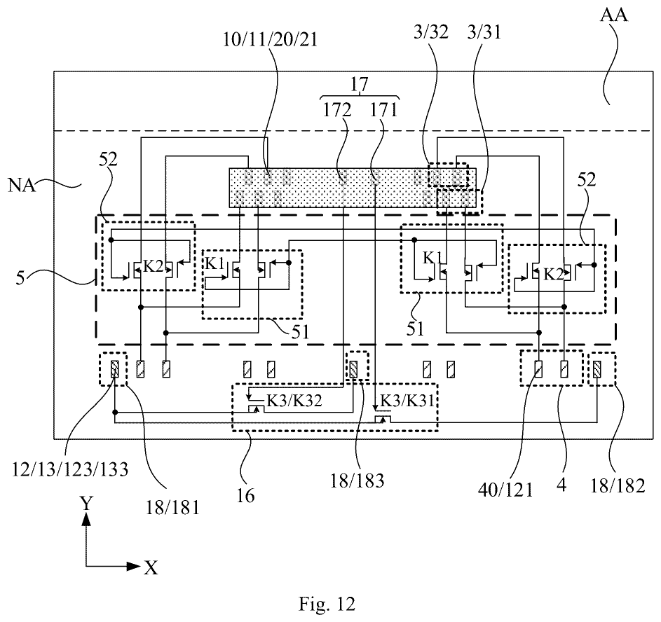

FIG. 12 is a schematic view of yet another display module according to an embodiment of the present application. In the embodiment shown in FIG. 12, the second gating circuit 16 includes two third switches K3, and the two third switches K3 are connected to different third test control terminals 17. Specifically, the display module may include three first test binding pads 123 and second test binding pads 133 corresponding to the three first test binding pads 123 to form three test binding structures 18, that is, a first sub-test binding structure 181, a second sub-test binding structure 182, and a third sub-test binding structure 183. Accordingly, the third switch K3 may include a first sub-switch K31 and a second sub-switch K32, and the third test console 17 may include a first sub-test console 171 and a second sub-test console 172. The first sub-test binding structure 181 and the second sub-test binding structure 182 are close to two side edges of the flexible circuit board (not shown in the drawings) in the first direction X, respectively, and the third sub-test binding structure 183 is disposed in a middle region of the flexible circuit board in the first direction X. A first end of the first sub-switch K31 may be connected to the first sub-test binding structure 181, a second end of the first sub-switch K31 may be connected to the second sub-test binding structure 182, and a control terminal of the first sub-switch K31 is connected to the first sub-testing control terminal 171. A first end of the second sub-switch K32 may be connected to the first sub-test binding structure 181, a second end of the second sub-switch K32 may be connected to the third sub-testing binding structure 183, and a control terminal of the second sub-switch K32 is connected to the second sub-testing control terminal 171.

The third testing phase may include a first sub-testing phase and a second sub-testing phase. In the first sub-testing phase, the first sub-testing control terminal 171 may be utilized to transmit an active level signal to the first sub-switch K31, and the second sub-testing control terminal 172 may be utilized to transmit an inactive level signal to the second sub-switch K32. The first sub-switch K31 connects the first sub-testing binding structure 181 and the second sub-testing binding structure 182 to form the third binding impedance testing circuit detecting binding state of both side edges of the flexible circuit board. In the second sub-testing stage, the second sub-testing control terminal 172 may be utilized to transmit an active level signal to the second sub-switch K32, and the first sub-testing control terminal 171 may be utilized to transmit an inactive level signal to the first sub-switch K31. The second sub-switch K32 connects the first sub-testing binding structure 181 and the third sub-testing binding structure 183 to form the third binding impedance testing circuit detecting the binding state of one side edge and the middle of the flexible circuit board. In this way, it is possible to detect the binding state of the different positions of the flexible circuit board.

Compared with directly shorting the two first test binding pads 123, the second gating circuit 16 can gate the two first test binding pads 123, which can improve the connection flexibility between different test binding structures 18, thereby meeting the detection requirements of binding conditions of the different binding positions between the flexible circuit board and the display panel 1.

Continuing to refer to FIG. 11, the driver chip 2 further includes a third control pin 203. The third control pin 203 serves as the third test control terminal 17 and is electrically connected to the control terminal of the second gating circuit 16.

The third control pin 203 may be other chip pins 20 than the test pin 21, the first control pin 201 and the second control pin 202, and the third control pin 203 may be disposed between the test pins 21 on two sides of the driver chip 2. In the binding impedance testing phase, the third control pin 203 can be used as the third test control terminal 17, and the third control pin 203 can transmit a test control signal to the third switch K3. After the display module is shipped from the factory, the third control pin 203 can normally serve as the signal transmission pin of the driver chip 2 during the normal use stage.

In other embodiments, the third test control terminal 17 may be the third binding pad 13 on the flexible circuit board 8. For example, the flexible circuit board 8 may provide the test control signal required by the second gating circuit 16 other than the third binding pad 13 bonded to the test pad 40 in the test pad unit 4 and the second test binding pad 133.

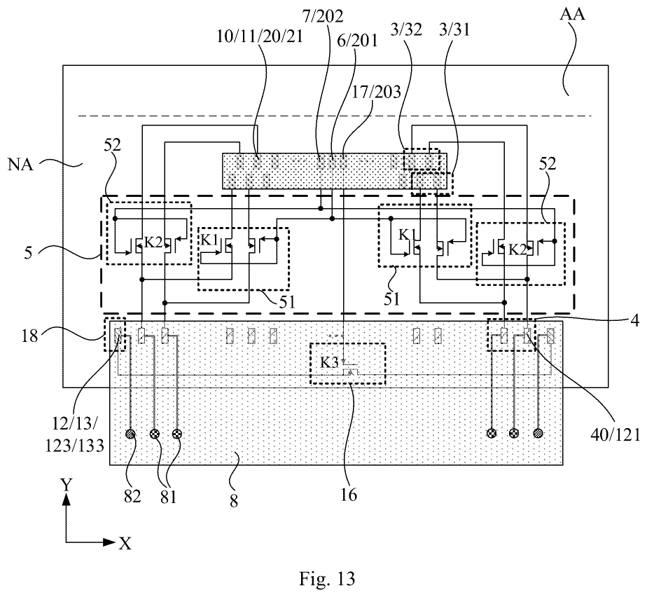

FIG. 13 is a schematic view of still yet another display module according to an embodiment of the present application. Referring to FIG. 13, in a possible embodiment, the flexible circuit board 8 may further include a plurality of first test points 81, which are respectively electrically connected to the third binding pads 13 corresponding to the test pad units 4 and are in contact with the test probes respectively for receiving the first impedance testing signal. Alternatively or additionally, the flexible circuit board 8 further includes at least two second test points 82, which are electrically connected to the second test binding pads 133 and are in contact with test probes for receiving the second impedance testing signal.

As shown in FIG. 13, in some embodiments, the plurality of test points may be provided on the flexible circuit board 8, and the test points are copper leakage test pads on the flexible circuit board 8. The test points may include first test points 81 and/or a second test points 82. The first test points 81 are connected to the first part of the third binding pads 13 through traces in the flexible circuit board 8. The second binding pads 12 that are correspondingly bonded to the first part of the third binding pads 13 are test pads in the test pad unit 4. In the first testing phase and the second testing phase, the test probes of the test equipment can be used to transmit the first impedance testing signal to the first test points 81, thereby transmitting the first impedance testing signal to the first binding impedance testing circuit or the second binding impedance testing circuit to detect the binding state of the driver chip 2.

The second test points 82 are connected to the second part of the third binding pads 13 through traces in the flexible circuit board 8, and the second part of the third binding pads 13 are second test binding pads 133. In the third testing phase, the test probes of the testing equipment can be used to transmit the second impedance testing signal to the second test point 82, thereby transmitting the second impedance testing signal to the third impedance testing circuit to realize detecting the binding state of the flexible circuit board 8. The first impedance testing signal may be the same as or different from the second impedance testing signal, and which are not limited in the embodiments of the present application.

In the embodiment shown in FIG. 13, the flexible circuit board 8 is provided with a first test point 81 and a second test point 82, which is not limited to this in practice, and in other embodiments, the flexible circuit board 8 may be provided with only the first test point 81 or only the second test point 82, or the test point may be canceled on the flexible circuit board 8. The test probes are utilized to directly contact the second binding pad 12 before binding the flexible circuit board 8, thereby realizing the binding state detection of at least one of the driver chip 2 or the flexible circuit board 8.

It is to be understood that the number of first test points 81 may be the same as the number of test pads 40, and the number of second test points 82 may be the same as the number of test binding structures 18. In some embodiments, the number of first test points 81 in the flexible circuit may be four, and the four first test points 81 are connected to four test pads 40 in the test pad unit 4, respectively. The number of second test points 82 may be two, and the two second test points 82 are connected to two test binding structures 18, respectively. The number of test points for binding impedance testing on the flexible circuit board 8 is reduced, thereby reducing the occupancy of the test points on the surface of the flexible circuit board 8, and the space saved can be used to lay out other structures, which is more conducive to the wiring in the flexible circuit board 8.

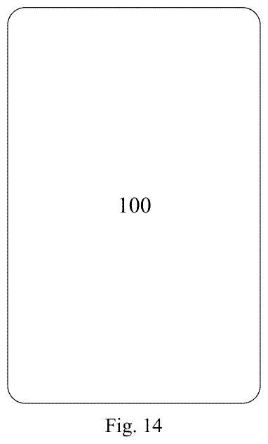

The embodiments of the present application further provide a display device. FIG. 14 is a schematic view of a display apparatus according to an embodiment of the present application. As shown in FIG. 14, the display device includes a display module 100 provided by any embodiment of the present application. Therefore, the display device provided by the embodiment of the present application has the corresponding beneficial effects of the display module provided by the embodiment of the present application, which will not be repeated herein. Exemplarily, the display device may be an electronic device such as a cellular phone, a computer, a smart wearable device (e.g., a smart watch), and an in-vehicle display device, and the embodiments of the present application are not limited thereto.

What is claimed is:

1. A display module comprising:
a display panel comprising a display area and a non-display area surrounding at least part of the display area;
a driver chip comprising a plurality of chip pins, the plurality of chip pins comprising test pins, the driver chip being bonded to the display panel to form at least two test binding units, each of which comprises at least two sets of correspondingly bonded test pins and first binding pads, and the first binding pads being disposed in the non-display area of the display panel; and
a test pad unit and a first gating circuit, the test pad unit being electrically connected to each of the test binding units through the first gating circuit, and being connected to the first binding pads and the test pins in each of the test binding units through the first gating circuit to form a binding impedance testing circuit.

2. The display module according to claim 1, wherein the at least two test binding units comprise at least one first test binding unit and at least one second test binding unit;
the first gating circuit comprises a first gating unit and a second gating unit, and the test pad unit is electrically connected to the first test binding unit through the first gating unit and electrically connected to the second test binding unit through the second gating unit; and
the display module has a first testing phase and a second testing phase, where in the first testing phase, the first gating unit is turned on to enable the test pad unit and the first test binding unit, and the test pad unit is connected to the first binding pads and the test pins in the first test binding unit to form a first binding impedance testing circuit; and where in the second testing phase, the second gating unit is turned on to enable the test pad unit and the second test binding unit, and the test pad unit is connected to the first binding pads and the test pins in the second test binding unit to form a second binding impedance testing circuit.

3. The display module according to claim 2, wherein the test pad unit comprises a test pad, the first gating unit comprises a first switch, the test pad is electrically connected to the first binding pads in the first test binding unit via the first switch;
the second gating unit comprises a second switch, and the test pad is electrically connected to the first binding pads in the second test binding unit via the second switch;
a control terminal of the first switch is connected to a first test control terminal, and a control terminal of the second switch is connected to a second test control terminal;
in the first testing phase, the first switch is turned on according to an active level signal transmitted by the first test control terminal, and the second switch is turned off according to an inactive level signal transmitted the second test control terminal; and
in the second testing phase, the first switch is turned off according to an inactive level signal transmitted by the first test control terminal, and the second switch is turned on according to an active level signal transmitted by the second test control terminal.

4. The display module according to claim 3, wherein the control terminal of each first switch in a same first gating unit is connected to a same first test control terminal, and the control terminal of each second switch in a same second gating unit is connected to a same second test control terminal.

5. The display module according to claim 3, wherein the at least two test binding units comprise at least two first test binding units and at least two second test binding units;
a number of the first gating units is same as a number of first test binding units, a number of second gating units is the same as a number of the second test binding units, the control terminals of the first switches in the first gating units are connected to the same first test second terminal, and the control terminals of the second switches in the second gating units are connected to the same second test control terminal.

6. The display module according to claim 5, wherein the at least two test binding units comprise two first test binding units and two second test binding units, the two first test binding units are close to opposite side edges of the driver chip in a first direction, respectively, the two second test binding units are close to opposite side edges of the driver chip in the first direction, respectively, and the first direction is parallel to an arrangement direction of the chip pins in the driver chip; and
the display panel comprises two test pad units, one of the test pad units is connected to one of the first test binding units through one of the first gating units, and is connected to one of the second test binding units through one of the second gating units.

7. The display module according to claim 3, wherein the chip pins further comprise a first control pin serving as the first test control terminal and electrically connected to the control terminal of the first switch, and a second control pin serving as the second test control terminal and electrically connected to the control terminal of the second switch.

8. The display module according to claim 3, further comprising a flexible circuit board bonded to the non-display area, and the first test control terminal and the second test control terminal being integrated into the flexible circuit board.

9. The display module according to claim 7, wherein the display panel further comprises a first test control signal line and a second test control signal line, the first test control signal line and the second test control signal line each being disposed on a side of the driver chip facing away from the display area; and
the control terminal of the first switch is electrically connected to the first test control terminal through the first test control signal line, and the control terminal of the second switch is electrically connected to the second test control terminal through the second test control signal line.

10. The display module according to claim 2, wherein the test pin in the first test binding unit is a signal input pin of the driver chip, and the test pin in the second test binding unit is a signal output pin of the driver chip.

11. The display module according to claim 1, wherein in each of the test binding units, the first binding pad comprises an input binding pad and an output binding pad, the test pin comprises a first test pin and a second test pin, the input binding pad is bonded to the first test pin, the output binding pad is bonded to the second test pin, and the first test pin and the second test pin are shorted;
the test pad unit comprises an input test pad connected to the input binding pad in the test binding unit through the first gating circuit, and an output test pad connected to the output binding pad in the test binding unit through the first gating circuit; and
the input test pad, the input binding pad, the first test pin, the second test pin, the output binding pad, and the output test pad are connected to form the binding impedance testing circuit.

12. The display module according to claim 1, further comprising a flexible circuit board bonded to the non-display area NA,
wherein the display panel further comprises a plurality of second binding pads, the flexible circuit board comprises a plurality of third binding pads, the second binding pads are correspondingly bonded to the third binding pads, respectively, and part of the second binding pads constitute the test pad unit.

13. The display module according to claim 12, wherein the second binding pads comprises at least one first test binding pad, the third binding pads comprises at least one second test binding pad, and the at least one first test binding pad is correspondingly bonded to the at least one second test binding pad to form a test binding structure; and
the first test binding pads in two of the test binding structures are electrically connected to enable the two test binding structures to be connected to form a third binding impedance testing circuit.

14. The display module according to claim 13, wherein the display panel further comprises a second gating circuit, a first end and a second end of the second gating circuit are respectively connected to different first test binding pads, and a control terminal of the second gating circuit is connected to a third test control terminal; and
the second gating circuit gates the two first test binding pads according to a control signal from the third test control terminal.

15. The display module according to claim 14, wherein the driver chip further comprises a third control pin serving as the third test control terminal and electrically connected to the control terminal of the second gating circuit.

16. The display module according to claim 14, wherein the plurality of second binding pads are arranged in the first direction parallel to an arrangement direction of the chip pins in the driver chip; and
the second binding pads comprise two first test binding pads disposed on two sides of the test pad unit in the first direction, respectively.

17. The display module according to claim 13, wherein the flexible circuit board further comprising a plurality of first test points electrically connected to the third binding pads corresponding to the test pad unit, respectively, and being in contact with a test probe for receiving a first impedance testing signal; or
the flexible circuit board further comprising at least two second test points electrically connected to the second test binding pads, and being in contact with a test probe for receiving a second impedance testing signal.

18. The display module according to claim 8, wherein the display panel further comprises a first test control signal line and a second test control signal line, the first test control signal line and the second test control signal line each being disposed on a side of the driver chip facing away from the display area; and
the control terminal of the first switch is electrically connected to the first test control terminal through the first test control signal line, and the control terminal of the second switch is electrically connected to the second test control terminal through the second test control signal line.

19. A display apparatus comprising a display module which comprises:
a display panel comprising a display area and a non-display area surrounding at least part of the display area;
a driver chip comprising a plurality of chip pins, the plurality of chip pins comprising test pins, the driver chip being bonded to the display panel to form at least two test binding units, each of which comprises at least two sets of correspondingly bonded test pins and first binding pads, and the first binding pads being disposed in the non-display area of the display panel; and
a test pad unit and a first gating circuit, the test pad unit being electrically connected to each of the test binding units through the first gating circuit, and being connected to the first binding pads and the test pins in each of the test binding units through the first gating circuit to form a binding impedance testing circuit.
